(19) United States
(12) Patent Application Publication
(10) Pub. No.: US 2008/0205557 A1
(43) Pub. Date: Aug. 28, 2008

(54) Systems and Methods for Performing External Correction

(75) Inventor: Yi He, Portland, OR (US)

Correspondence Address: MATTHEW D. RABDAU;TEKTRONIX, INC., 14150 S.W. KARL BRAUN DRIVE, P.O. BOX 500 (50-LAW), BEAVERTON, OR, 97077-0001, US

(73) Assignee: TEKTRONIX, INC., Beaverton, OR (US)

(21) Appl. No.: 12/037,282

(22) Filed: Feb. 26, 2008

Related U.S. Application Data
(60) Provisional application No. 60/891,921, filed on Feb. 27, 2007.

(51) Int. Cl. H03D 1/00; H03M 1/12

(52) U.S. Cl. 375/340; 341/155

(57) ABSTRACT

A system is provided for performing external correction to reduce, or eliminate, the frequency dependent response related to an external device for receiving analog signals. The system includes an ADC and a spectrum processor for converting time-domain digital data into a spectrum. An external correction is provided between the ADC and the spectrum processor to reduce, or eliminate, the frequency dependent response associated with the external device. A corresponding method is provided that determines the frequency response of the external device, determines the gain at the center frequency, determines the normalized frequency response, constructs and inverse filter and applies the inverse filter to the digitized time-domain data and scales the results prior to any conversion, or transformation, into the frequency domain.

### BACKGROUND

The present invention relates to test and measurement instruments employing external devices for receiving signals for measurement and testing.

Test and measurement instruments, such as oscilloscopes, spectrum analyzers, or field test equipment, often rely on external devices to obtain signals to be measured or tested. These external devices, such as antennas, cables, preamplifiers, or probes, often have frequency-dependent frequency response. This frequency response is non uniform, meaning that the amplitude gains vary at different frequencies. Therefore, the received signal on the instrument is distorted after passing through the external devices in the receiver path. The compensation of the distortion in the signal is useful for producing corrected signals. This compensation is referred to as external correction.

In the case of a spectrum analyzer 10, as shown in FIG. 1 (prior art), the external correction is applied after spectrum processing, which converts the time-domain digital data into the frequency domain. The input signal first passes through an external device 12, which may be for example an antenna, a pre-amplifier, or a probe. After passing through the external device 12, the signal enters an RF input of the spectrum analyzer 10. The external device may be composed of multiple external devices, for example an antenna connected through a cable to a preamplifier prior to being input to the instrument. As shown in FIG. 1, the input signal enters the RF input and passes through a frequency selective filter 14, a mixer 16, and an anti-alias filter 18 to provide an intermediate frequency (IF) to the analog to digital converter (ADC) 20. Although there is only one mixer shown, multiple frequency conversion stages may be used in some applications. The IF may be equivalent to a base band in some applications. After the ADC produces a digital signal, the digital intermediate-frequency (DIF) block 22 converts the digital IF signal to the base-band in-phase (I) and quadrature (Q) data. A spectrum processing block 24 transforms the IQ data, which is time-domain data, into a spectrum, which is frequency-domain data. The spectrum processing block 24 may utilize a Fast Fourier Transform (FFT) to perform the transformation into the frequency-domain. In spectrum analyzers as shown in FIG. 1, the external correction is performed using software after the spectrum processing, as shown by s/w external correction block 26 prior to displaying the spectrum on the display 28. The external correction is applied by scaling the spectrum results with the reciprocal of the frequency response of the external device before sending the spectrum to the display. The spectrum analyzer 10 also includes additional storage and processors, including CPUs, to provide set-up and control, as well as running the external correction and generating the display. As storage and processors are well understood, no additional detail is needed here.

Since the system and method shown in FIG. 1 applies the external correction towards the end of the processing chain, it suffers from several drawbacks. When additional measurements are implemented, for example through upgrades, the external correction may need to be extended or modified as well. Also, it is not possible to incorporate the phase response of the external device for vector analysis such as modulation analysis since the phase information is lost prior to the external correction. In addition, when the resolution bandwidth (RBW) is large and is comparable to the amplitude-changing period of the external device, the system and method shown in FIG. 1 results in inaccurate spectrum shape. If the input signal is a continuous wave (CW) signal and the spectrum analyzer is tuned to the frequency of the signal, the spectrum should exhibit the shape of the RBW filter. However, the resulting spectrum in the system shown in FIG. 1, displays the reciprocal of the frequency response on top of the RBW filter shape.

### SUMMARY

Accordingly, an embodiment of the invention is shown in FIG. 2. This embodiment applies the external correction prior to spectrum processing. Furthermore, in some embodiments, the system also enables correction in the time-domain prior to other processing such as trigger processing, or digital phosphor display. In further embodiments, the external correction is implemented using hardware.

### BRIEF DESCRIPTION OF THE DRAWINGS

FIG. 1 (Prior Art) illustrates spectrum analyzer with post spectrum processing external correction.

FIG. 2 illustrates a spectrum analyzer with external compensation prior to spectrum processing.

FIG. 3 is a flow diagram of an embodiment of a method of providing external compensation.

FIG. 4 is a flow diagram of an embodiment of a method of providing external compensation in connect with a stepping the center frequency.

FIG. 5 illustrates an embodiment of a system including external correction.

FIG. 6 illustrates an embodiment of a system including external correction.

FIG. 7 illustrates an embodiment of a system including external correction.

### DETAILED DESCRIPTION

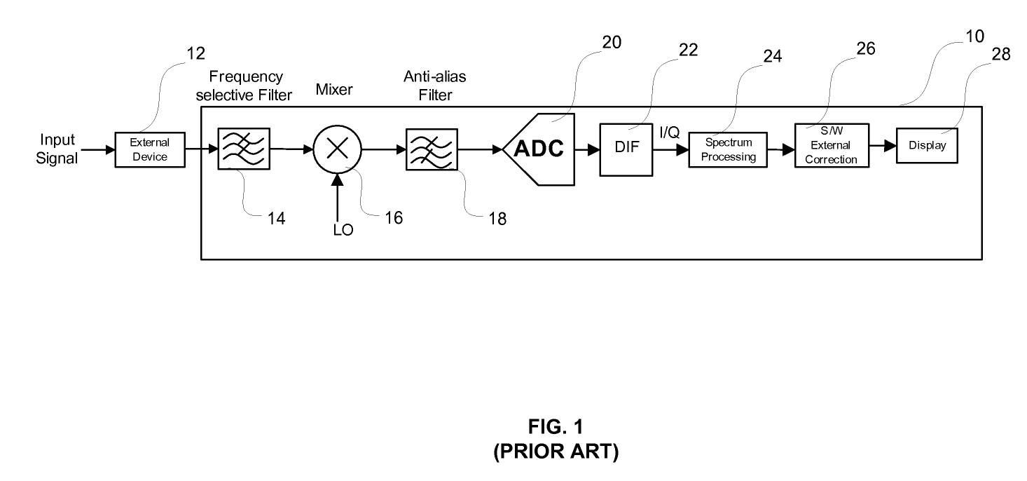

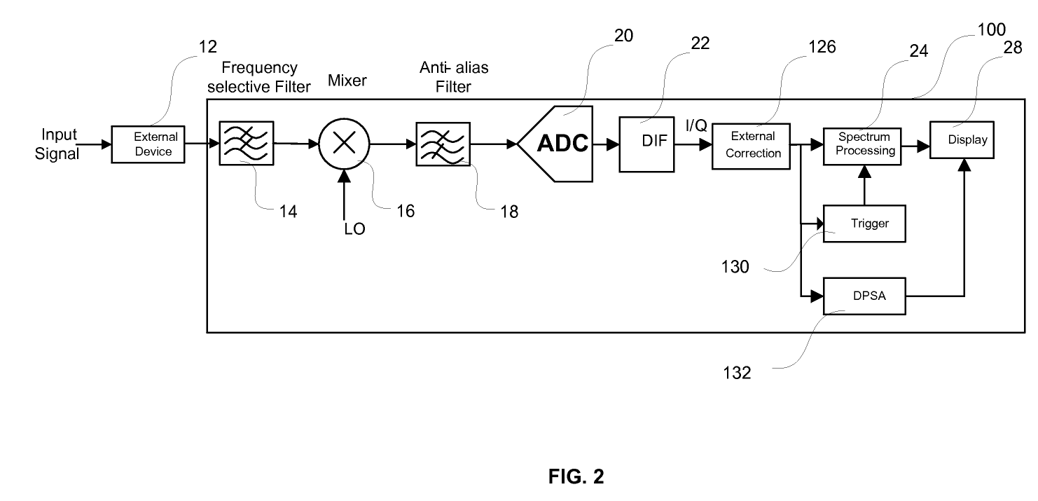

A first embodiment of the present system 100 is shown in FIG. 2. The system 100 is a spectrum analyzer similar to that shown in FIG. 1, but with the external correction 126 provided prior to spectrum processing 24. In addition, as shown in FIG. 2, the output of the external correction 126 may also be used by the trigger generator 130, and digital phosphor display processor 132. Digital phosphor display refers to a type of display used for example in Digital Phosphor Oscilloscopes, for example those that use a fast rasterization and decay process to emulate the look and feel of an analog phosphor display, for example by varying intensity. Alternatively, pseudo-color, or thermal-color, is used to produce a display based upon attack and decay settings.

Given the frequency response of the external device, which may be provided in some embodiments as a table of correction values, a digital filter h(n) is constructed corresponding to:

$$H ( w ) = \frac{1}{D ( w )} , where wc - BW / 2 \leq w \leq wc + BW / 2$$

where H(w) is the frequency response of the digital filter, D(w) is the frequency response of the external device, BW is the DIF acquisition bandwidth and wc is the center frequency. In an embodiment of the present invention, the frequency response of the external device (D(w)) is provided as the combined frequency response of all external devices in the signal path. In various embodiments D(w) is provided as a complex function containing both amplitude response and phase response, just amplitude response, or just phase response.

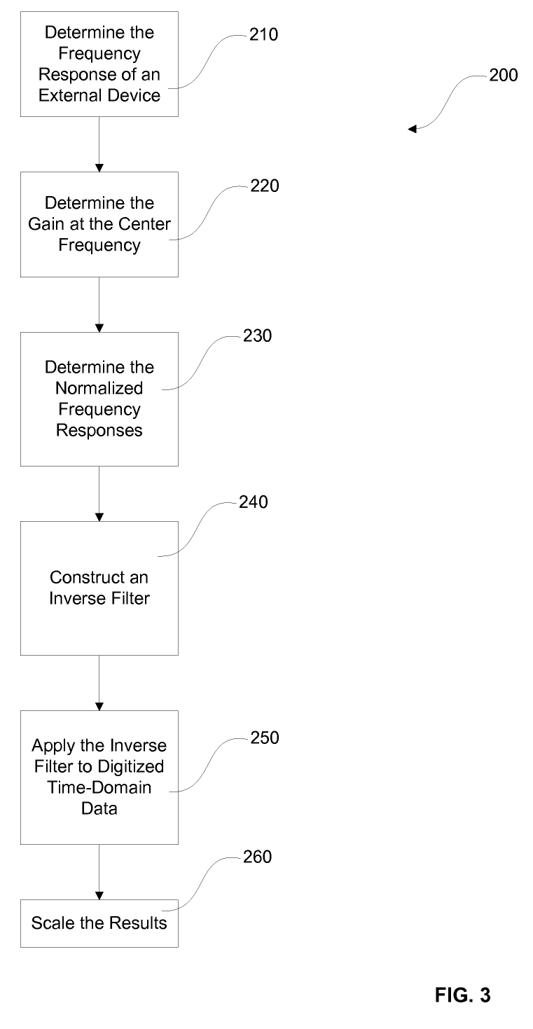

An embodiment of a method 200 for providing external correction is shown in FIG. 3. The frequency response D1(w) of the external device is determined, as shown at step 210. In some embodiments, the frequency response of the external device covers the entire frequency range of interest. In other embodiments, extrapolation may be used to expand the frequency range from that initially provided. In further embodiments, where the frequency response is not available over the entire range of interest, a proper error is indicated to the user.

In an embodiment of the method, the frequency response is determined over the acquisition bandwidth (BW) at a given tuning center frequency (wc), such that the frequency response is determined from wc−BW/2 through wc+BW/2. In some embodiments, the external device consists of multiple external devices, such as antenna, cable, and pre-amp connected together. The frequency response of the combined external device may be determined from a single external correction table based upon the characterization of the entire combined external device. In other embodiments, each external device that makes up the combined external device has its own external correction table. A combined external correction table is obtained by combining the individual correction tables. In some embodiments, for example when all the tables do not share the same frequencies, interpolation is used to allow the combining of multiple eternal correction tables into a composite frequency response. While in many embodiments it would be preferable for the composite frequency response to include all the external devices making up the external device, in some embodiments it may be sufficient to only combine the most significant external devices when determining the composite frequency response.

As shown at step 220, the gain G(wc) at the center frequency, wc, is determined. The combined frequency response is separated into two parts: frequency-independent constant gain and frequency-dependent response. The normalized response D2(w) to the center frequency is determined at step 230. The composite frequency response D1(w) is normalized using the gain at the center frequency to produce the normalized response D2(w), (D2(w)=D1(w)/G(wc). In some embodiments, this will reduce, or eliminate, the quantization error of the filter coefficients, since the fixed point operations are often implemented on the hardware.

Step 240 provides for constructing an inverse filter, as described above, with a frequency response corresponding to the reciprocal of the normalized frequency response (1/D2(w)). The filter coefficients are provided to the external correction block. The number of taps used in the digital filter is determined by the amplitude flatness and phase linearity, as well as the distortion introduced by the external devices, or device. In some embodiments, this external correction block is provided as hardware, such as an FPGA, a DSP, or an ASIC, configured to provide digital filtering. At the present time, a hardware implementation is preferred as it provides higher processing speeds for implementing the filters to provide real-time processing. In future embodiments, it would be foreseeable to use software running on a general purpose processor, or CPU, to provide the external correction block, even in the present method of providing frequency correction in the time domain.

The inverse filter provided in the external correction block is now applied to the digitized time-domain data provided by the ADC, as shown at step 250. In some embodiments, the digitized time-domain data has been further processed by the DIF processing block, which may provide for example base-band IQ data.

Results from the external correction block are scaled as provided at step 260. This scaling is based on the gain G(wc) determined previously. In some embodiments, the scaling occurs in the frequency domain, after transformation by the spectrum processing block. In other embodiments, the scaling occurs on the time-domain data. In further embodiments, the scaling may be provided in the time-domain for some processes, such as triggering, and in the frequency-domain for other processes.

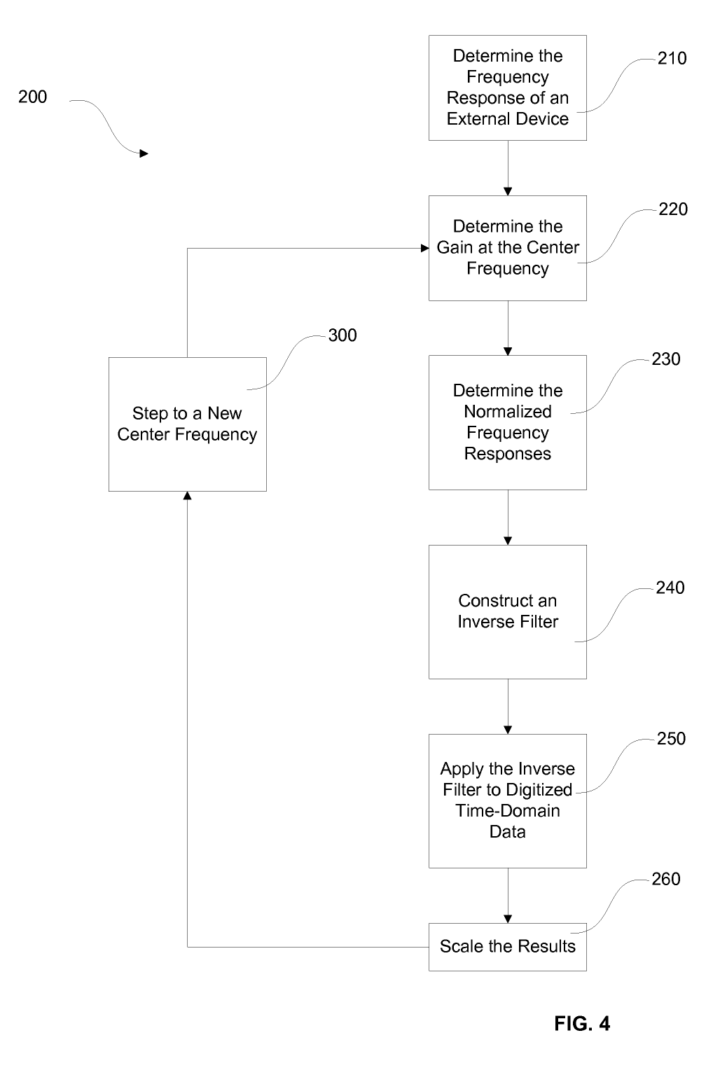

FIG. 4 illustrates another embodiment of the method that would be employed for example when a spectrum analyzer is operated in a stepped mode. In the stepped mode, the spectrum is stitched together from spectrum measured using multiple acquisitions tuned to different center frequencies. In stepped mode, embodiments of the present method can provide external device correction by tuning the center frequency in steps, as provided at step 300, and repeating process steps 220 through 260 for each center frequency. In some embodiments, step 220 will simply reuse the external frequency response previously determined. In other embodiments, step 210 will be repeated as well so that the determination of the external frequency response will be updated as the frequency is stepped. In some embodiments, the center frequency is tuned by controlling the local oscillators in the mixers. In further embodiments, the filter coefficients are saved in memory so that the computation of the filter coefficients is only done once. Calculating the filter coefficients only once increases the speed at which the spectrum measurements are made while providing external correction.

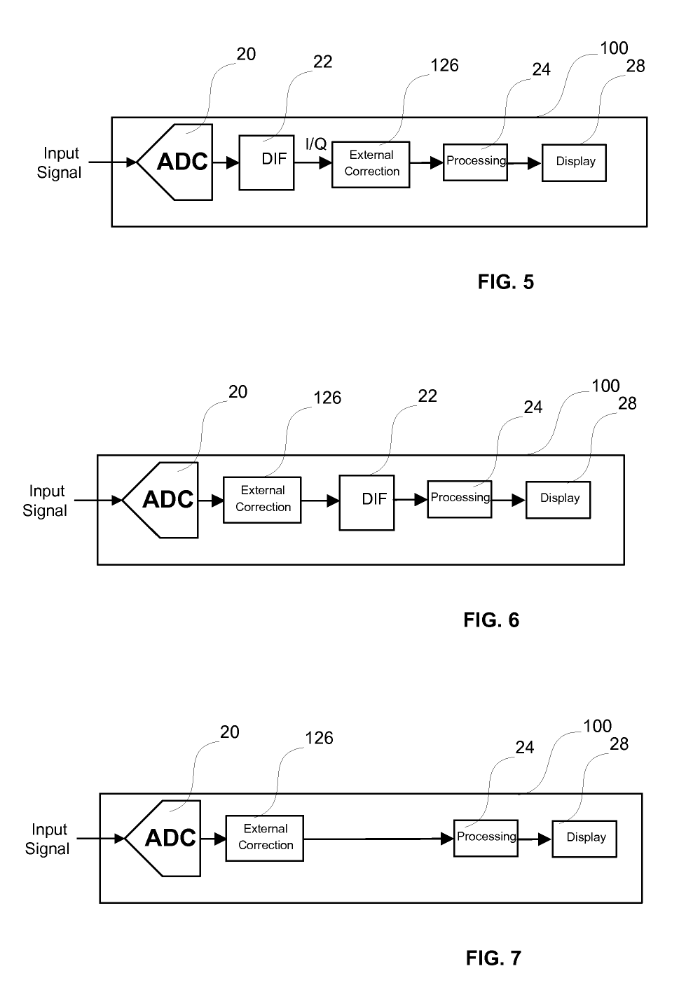

As shown in FIG. 5, embodiments of the present invention do not require a down-converter, or mixer. In some embodiments, external correction is provided based upon the output on the ADC regardless of any conditioning, or lack thereof, of the input signal.

As shown in FIG. 6, in additional embodiments the external correction is provided prior to the digital intermediate-frequency (DIF) block 22. In some embodiments, the external correction is based on real-valued output from the ADC. In various other embodiments, the ADC output can be digital intermediate-frequency (DIF) components or base-band. Depending upon the implementation of each embodiment, the ADC output may be complex I and Q signals, or generated from the real components only.

As shown in FIG. 7, the DIF block 22 may be eliminated completely from some embodiments.

Although some of the embodiments described herein are related to spectrum analyzers, other embodiments would be suitable for time-domain processing or measurements. The embodiments would not require transformation to a frequency domain, or the creation of any spectrum.

What is claimed is:

1. A system for performing external correction comprising:
an external device for receiving an analog signal, wherein the external device has a frequency dependent response;
an analog to digital converter that converts the analog signal into a time-domain digital signal;
a spectrum processor that transforms the time-domain digital signal into a spectrum; and
external correction connected between the analog to digital converter and the spectrum processor that provides correction for the frequency dependent response of the external device.

2. The system as claimed in claim 1, wherein the external correction comprises a digital filter.

3. The system as claimed in claim 2, further comprises a digital intermediate frequency block that converts the time-domain digital signal to base-band in-phase and quadrature data.

4. The system as claimed in claim 3, wherein the digital intermediate frequency block is connected between the analog to digital converter and the external correction.

5. The system as claimed in claim 3, wherein the digital intermediate frequency block is connected between the external correction and the spectrum processor.

6. The system as claimed in claim 1, further comprising a trigger circuit connected after the external correction.

7. The system as claimed in claim 1, further comprising a digital phosphor display processor connected after the external correction.

8. A method of performing external correction comprising:
determining a frequency response of an external device;
determining a gain at the center frequency;
determining a normalized frequency responses;
constructing an inverse filter;
applying the inverse filter to digitized time-domain data; and
scaling the results.

9. The method as claimed in claim 8, wherein determining a frequency response comprises determining a combined frequency response of multiple connected external devices.

10. The method as claimed in claim 9, wherein the combined frequency response is determined by combining the frequency response of each individual external device taken from its own external correction table.

11. The method as claimed in claim 9, wherein the combined frequency response is obtained from a single external correction table based upon a characterization of an entire combined external device.

12. The method as claimed in claim 8, further comprising stepping to a new center frequency after scaling the results and returning to the step of determining the gain at the center frequency.
